(19) United States
(12) Patent Application Publication
(10) Pub. No.: US 2010/0246135 A1
(43) Pub. Date: Sep. 30, 2010

(54) ELECTRONIC DEVICE

(75) Inventors: Masanori Hongo, Osaka (JP); Takuma Hitomi, Osaka (JP); Hideki Ito, Osaka (JP); Kiyoshi Yamakoshi, Osaka (JP); Masami Fukuyama, Osaka (JP); Hideki Takagi, Osaka (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: SANYO ELECTRIC CO., LTD., Osaka (JP); SANYO TUNER INDUSTRIES CO., LTD., Osaka (JP)

(21) Appl. No.: 12/731,827

(22) Filed: Mar. 25, 2010

(30) Foreign Application Priority Data
Mar. 31, 2009 (JP) 2009-085760

(51) Int. Cl. H05K 7/20

(52) U.S. Cl. 361/707

(57) ABSTRACT

An electronic device of the present invention includes: a base made of a ceramic material; an electronic device element arranged in a central area of the upper surface of the base, in a way that the electronic device element is placed on a first heat transfer layer; a first heat dissipation layer formed in a central area of the lower surface of the base; a plurality of thermal vias arranged in the base, and which connects the first heat transfer layer and the first heat dissipation layer; and a second heat transfer layer buried in the base, the second heat transfer layer crossing the plurality of thermal vias, while extending from a position above a central area of the lower surface of the base to a position above a peripheral area of the lower surface of the base.

The Japanese application Number 2009-085760, upon which this patent application is based, is hereby incorporated by reference.

### BACKGROUND OF THE INVENTION

1. Field of the Invention

The present invention relates to an electronic device including an electronic device element arranged in a cavity.

2. Description of Related Art

A conventionally employed package to contain a light emitting device element is configured as an integrated structure with a base 200 and a frame 300 each made of a ceramic material as shown in FIG. 15. A cavity 3a for holding a light emitting device element 100 therein is defined inside the frame 300.

As shown in FIG. 15, thermal vias 400 can be defined in the base 200 made of a ceramic material. The package in which the thermal vias 400 are defined in the base 200 is capable of dissipating heat generated at the light emitting device element 100 arranged in the cavity 3a to outside. The thermal vias 400 are made by filling vias penetrating the base 200 with a metallic paste and the like.

In the package in which the thermal vias 400 penetrate the base 200 from its upper surface to its lower surface so that the thermal vias 400 are exposed in the cavity 3a, heat generated at the light emitting device element 100 arranged in the cavity 3a is carried through the thermal vias 400 toward the lower surface of the base 200.

However, a thermal via defined in the conventional package does not provide sufficient heat dissipation capability for a light emitting device element, causing a problem such as degradation by heat in the performance of the light emitting device element. Insufficient heat dissipation capability is not only the problem of an electronic device including a light emitting device element, but is also a problem of an electronic device including an electronic device element of other types. Another problem such as warpage also arises when a package to contain an electronic device element is made of a ceramic material.

### SUMMARY OF THE INVENTION

In an electronic device with a package to contain an electronic device element such as a light emitting device element or an integrated circuit, it is an object of the present invention to achieve high heat dissipation capability and alleviate the warpage of the package.

A first aspect of the electronic device of the present invention includes: a base made of a ceramic material; an electronic device element arranged in a central area of the upper surface of the base, in a way that the electronic device element is placed on a first heat transfer layer made of a metallic material; a first heat dissipation layer made of a metallic material, and which is formed in a central area of the lower surface of the base; a plurality of thermal vias made of a metallic material and arranged in the base, and which connects the first heat transfer layer and the first heat dissipation layer; and a second heat transfer layer made of a metallic material and buried in the base, the second heat transfer layer crossing the plurality of thermal vias, while extending from a position above the central area of the lower surface of the base to a position above a peripheral area of the lower surface of the base.

In the electronic device of the first aspect, heat generated at the electronic device element is discharged from the first heat dissipation layer after passing through the thermal vias. The heat is also carried to the second heat transfer layer through the thermal vias. So, the heat generated at the electronic device element is transferred throughout the base, and is then discharged from the whole of the electronic device.

A conventional electronic device suffers from warpage of the base. However, by the presence of the second heat transfer layer formed in the base, the electronic device of the first aspect can control the warpage of the base.

According to a second aspect of the electronic device of the present invention, the electronic device of the first aspect further includes: a second heat dissipation layer made of a metallic material, and which is formed in a peripheral area of the lower surface of the base; and a plurality of second thermal vias made of a metallic material and buried in the base, and which connects the second heat transfer layer and the second heat dissipation layer.

In the electronic device of the second aspect, the second heat transfer layer and the second heat dissipation layer are connected by the plurality of second thermal vias. This allows heat to be transferred throughout the base, so that the heat is efficiently dissipated throughout the base.

According to a third aspect of the electronic device of the present invention, in the electronic device of the first or second aspect, the second heat transfer layer extends to reach a side surface of the base at which an end portion of the second heat transfer layer is exposed.

In the electronic device of the third aspect, heat is discharged more efficiently to the outside of the base by the exposure of the second heat transfer layer at the side surface of the base.

According to a fourth aspect of the electronic device of the present invention, the electronic device of any one of the first to third aspects further includes a frame made of a ceramic material and arranged on the upper surface of the base. The frame has a cavity formed therein defined by the inner peripheral surface of the frame and the upper surface of the base, and the electronic device element is arranged in the cavity.

According to a fifth aspect of the electronic device of the present invention, the electronic device of any one of the first to fourth aspects further includes a side via buried in the base, and which extends from a portion of the second heat transfer layer defined above the peripheral area of the lower surface of the base to reach the lower surface of the base.

### BRIEF DESCRIPTION OF THE DRAWINGS

FIG. 1 is a perspective view of an electronic device of a first preferred embodiment of the present invention with a package to contain an electronic device element;

FIG. 2 is a sectional view taken along a line A-A shown in FIG. 1, and which explains a process of forming a ceramic body;

FIG. 3 is a sectional view of the package, in a state after a ceramic stacked structure is fired;

FIG. 4 is a sectional view of the package with an electronic device element arranged therein;

FIG. 5 is a sectional view in which the electronic device element is covered with resin;

FIG. 6 is a sectional view taken along the line A-A shown in FIG. 1, and which explains a process of forming a ceramic body about a package of a second preferred embodiment of the present invention to contain an electronic device element;

FIG. 7 is a sectional view of the package of the second preferred embodiment, in a state after a ceramic stacked structure is fired;

FIG. 8 is a sectional view of the package of the second preferred embodiment with an electronic device element arranged therein;

FIG. 9 is a sectional view of the package of the second preferred embodiment, in a state after resin is applied to fill a cavity;

FIG. 10 is a sectional view showing an exemplary arrangement of electrodes of the second preferred embodiment;

FIG. 11 is a sectional view of a package of a third preferred embodiment of the present invention to contain an electronic device element, in a state after resin is applied to fill a cavity;

FIG. 12 is a sectional view of a package of a fourth preferred embodiment of the present invention to contain an electronic device element, in a state after resin is applied to fill a cavity;

FIG. 13 is a sectional view of another package of the fourth preferred embodiment to contain an electronic device element, in a state after resin is applied to fill a cavity;

FIG. 14 is a sectional view of still another package of the fourth preferred embodiment to contain an electronic device element, in a state after resin is applied to fill a cavity; and

FIG. 15 is a sectional view of a conventional package to contain an electronic device element.

### DETAILED DESCRIPTION OF THE EMBODIMENTS

Preferred embodiments of the present invention are described in detail below with reference to drawings.

### First Preferred Embodiment

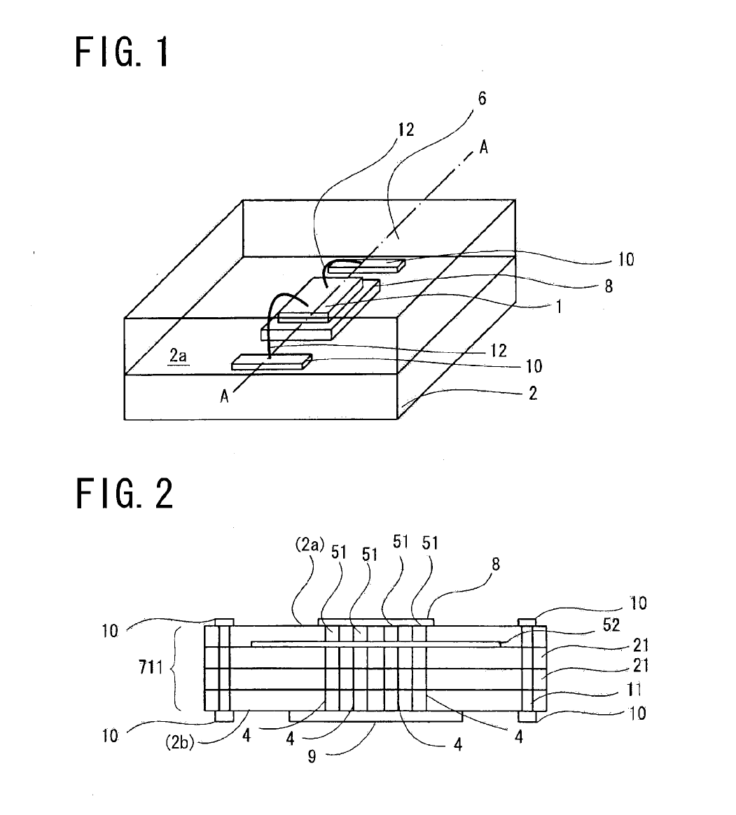

FIGS. 1 to 5 are sectional views showing an electronic device in its finished state according to a first preferred embodiment of the present invention, and showing process steps of manufacturing the electronic device. The sectional views of FIGS. 2 to 5 are taken along a line A-A shown in FIG. 1. The sectional views of FIGS. 6 to 14 referred to in second to fourth preferred embodiments are also taken along the line A-A.

As shown in FIG. 1, the electronic device of the first preferred embodiment includes a base 2 made of a ceramic material. An upper surface 2a of the base 2 holds thereon a first heat transfer layer 8, an electronic device element 1, electrodes 10 (that may be positive and negative electrodes), metal wires 12 for making connection to the electronic device element 1, and resin 6 containing a fluorescent substance. A first heat dissipation layer 9 (not shown in FIG. 1) is provided on the lower surface of the base 2.

In a process of forming a ceramic body, a plurality of ceramic sheets 21 made of an insulative ceramic material are stacked, so that a stacked structure 711 (to become the base 2 after being sintered) of the ceramic sheets 21 is formed as shown in FIG. 2. The process also includes formation of the first heat transfer layer 8, on which the electronic device element 1 is to be arranged, in a central area of the upper surface of the stacked structure 711 (to become the base 2 after being sintered). The process further includes formation of the electrodes 10, to be connected to the electronic device element 1, in a peripheral area of the upper surface of the stacked structure 711. The process still includes formation of the first heat dissipation layer 9 in a central area of the lower surface of the stacked structure 711 (to become the base 2 after being sintered), and formation of the electrodes 10 in a peripheral area of the lower surface of the stacked structure 711. The process further includes formation of vias 11 for making connection between the electrodes 10 on the upper surface and the electrodes 10 on the lower surface, and filling of the vias 11 with an electrode paste. Alternatively, the first heat transfer layer 8, the electrodes 10, and the first heat dissipation layer 9 may be formed after the stacked structure 711 is fired to form the base 2.

A plurality of vias 4 filled with a metallic paste and the like are defined in each of the stacked ceramic sheets 21. The arrangement of the vias 4 is such that the vias 4 defined in adjacent upper and lower ones of the ceramic sheets 21 overlap each other. So, after the vias 4 are sintered, the overlapping vias 4 are coupled to form thermal vias 51. Thus, the first heat transfer layer 8 and the first heat dissipation layer 9 are connected to each other through the thermal vias 51.

In the formation of the stacked structure 711 (to become the base 2 after being sintered), a second heat transfer layer 52 is formed between two of the upper and lower ones as a pair of the plurality of ceramic sheets 21. To be more specific, the second heat transfer layer 52 crosses the thermal vias 51 in a position above the central area of the lower surface of the stacked structure 711 (to become the base 2 after being sintered), while extending to positions above the peripheral area of the lower surface of the stacked structure 711 (to become the base 2 after being sintered).

The thermal vias 51 and the second heat transfer layer 52 are each made of metal of high thermal conductivity such as silver (Ag) or copper (Cu). Low temperature co-fired ceramic (LTCC) is used as a material of the ceramic sheets 21, so that the ceramic sheets 21 can be fired simultaneously with the first and second heat transfer layers 8 and 52. When the thermal vias 51 and the second heat transfer layer 52 are each made of a high melting point metallic material, a ceramic material for high temperature firing can be used as a material of the ceramic sheets 21.

The first heat dissipation layer 9 serves as a connection part in soldering to a circuit board or a heat dissipation plate. However, forming the first heat dissipation layer 9 on the lower surface of the stacked structure 711 (to become the base 2 after being sintered) results in a fear of the warpage of the base 2 formed by firing the stacked structure 711. In response, by adjusting the thickness of the second heat transfer layer 52 to make the second heat transfer layer 52 greater or smaller in thickness than the first heat dissipation layer 9, the warpage of the sintered base 2 can be controlled. So, by adjusting the thickness of the second heat transfer layer 52, the electronic device in its finished state has a small amount of warpage of the base 2.

When a light emitting device element is employed as the electronic device element 1, the second heat transfer layer 52 further serves as a reflecting layer off which light emitted from the light emitting device element reflects. The second heat transfer layer 52 is buried in the base 2. So, there will be no reaction or the like to be generated between the resin 6 containing a fluorescent substance and the second heat transfer layer 52, thereby preventing reduction in reflectivity to occur as a result of the reaction or the like therebetween.

Reflectivity changes with the order silver>LTCC>gold. Silver, when directly touching the resin 6 containing a fluorescent substance used in a latter step, causes a reaction such as oxidation (sulfuration), by which reflectivity of silver is reduced. In contrast, LTCC and gold, even when directly touching the resin 6, causes substantially no reaction. So, preferable formation of the upper surface 2a of the base 2 is such that LTCC, having high reflectivity and causing substantially no reaction with the resin 6, be exposed in an extensive area, and only an area in which the light emitting device element is to be arranged be covered by the first heat transfer layer 8. That is, preferable arrangement of the first heat transfer layer 8 on the upper surface 2a of the base 2 is such that, when a line is drawn from the first heat transfer layer 8 toward the outer periphery of the base 2, the line necessarily pass through the area in which LTCC is exposed. The electrodes 10 are preferably made of gold.

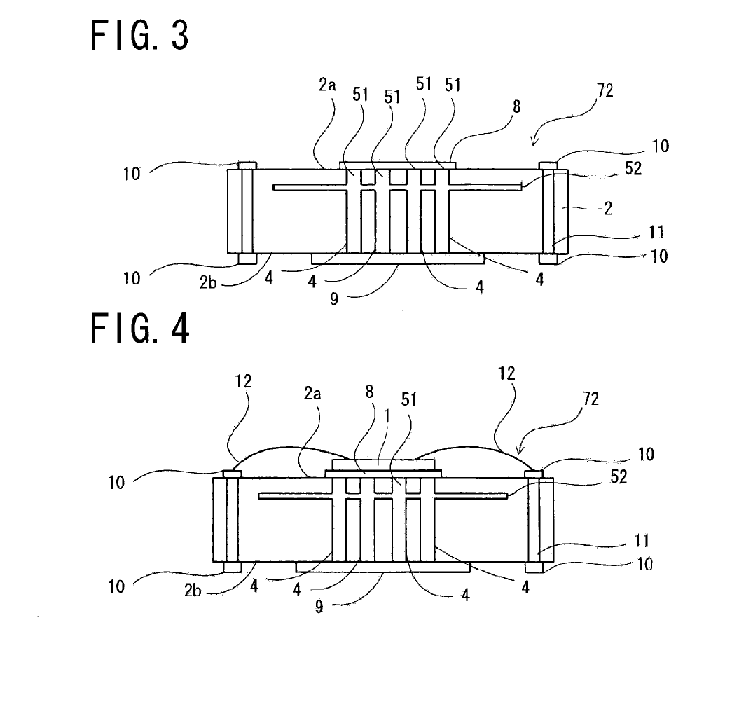

In a subsequent firing process, the stacked structure 711 is fired. Then, as shown in FIG. 3, the vias 4 defined in the stacked structure 711 are coupled together, so that the thermal vias 51 that penetrate the base 2 from the upper surface 2a to the lower surface 2b are defined. Further, each of the thermal vias 51 and the second heat transfer layer 52 crossing each other are joined together, by which a package 72 is completed.

In the first preferred embodiment, low temperature co-fired ceramic (LTCC) is used as a material of the base 2, so it can be fired at a temperature from 800° C. to 1000° C. This enables sintering of the stacked structure 711 without an undesirable event such as abnormal shrinkage of a metallic material used for forming the thermal vias 51, the first and second heat transfer layers 8 and 52, and the first heat dissipation layer 9.

The second heat transfer 52 is made mainly of metal, and is softer than ceramic accordingly. So, expanding the cross-sectional area of the second heat transfer layer 52 for better heat transfer capability that extends in parallel with the upper surface 2a of the base 2 easily makes the cross section of the sintered second heat transfer layer 52 concave, and easily weakens the strength of the package 72 itself. In response, in the first preferred embodiment, the second heat transfer layer 52 is placed between the ceramic sheets 21. So, the second heat transfer layer 52 resists being made concave, and the strength of the package 72 is hardly weakened. Further, as the second heat transfer layer 52 crosses each of the thermal vias 51, heat is easily dissipated throughout the base 2.

The cross-sectional area of the vias 4 defined below the electronic device element 1 is made smaller with the smaller size of the electronic device element 1. In response, the structure of the first preferred embodiment can expand the total heat dissipation area of the thermal vias 51 and the second heat transfer layer 52.

In a subsequent process of arranging the electronic device element 1, as shown in FIG. 4, the electronic device element 1 is arranged on the first heat transfer layer 8 fired in the firing process. The electronic device element 1 is thereafter connected by the metal wires 12 to the electrodes (formed of metal or the like) and others.

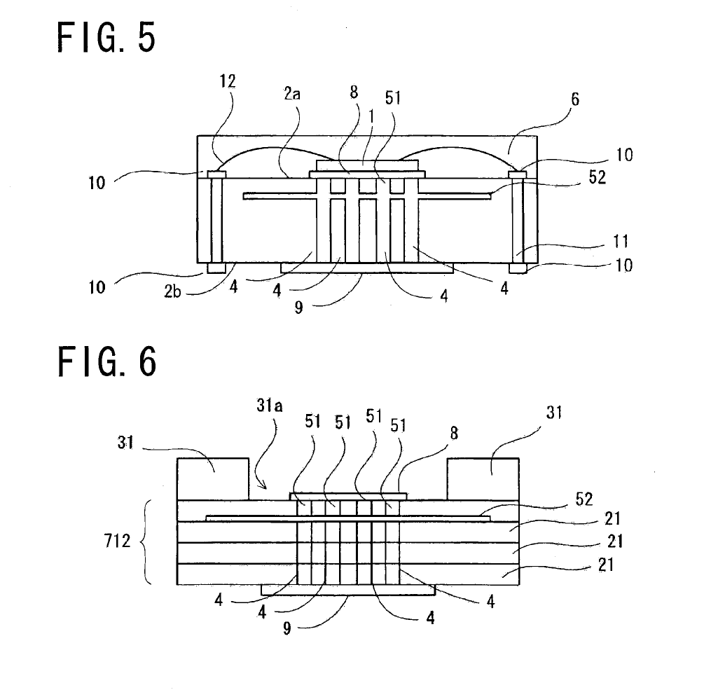

Next, in a process of covering the upper surface 2a of the base 2 with the resin 6 containing a fluorescent substance, the resin 6 containing a fluorescent substance is applied to cover the electronic device element 1 as shown in FIG. 5, and the applied resin 6 is cured. Then, the electronic device according to the first preferred embodiment is completed.

In the completed electronic device, heat generated at the electronic device element 1 goes to the first heat transfer layer 8, then reaches the lower surface 2b of the base 2 after passing through the thermal vias 51, and is thereafter dissipated from the lower surface 2b. At this time, the heat is also transferred to the second heat transfer layer 52 from the thermal vias 51, and the transferred heat spreads through the base 2. So, the heat generated at the electronic device element 1 can efficiently be discharged from the whole of the electronic device.

Formation of the first heat transfer layer 8 and the first heat dissipation layer 9 results in increase in the degree of warpage of the base 2. However, the second heat transfer layer 52 formed in the base 2 serves to alleviate the warpage of the base 2.

The above-described electronic device is of a structure that achieves efficient heat dissipation even if the first heat transfer layer 8 held on the upper surface 2a of the base 2 is the same in size as the electronic device element 1. So, when the electronic device element 1 is a light emitting device element, reduction in reflectivity is prevented by controlling the area of the first heat transfer layer 8 to its minimum possible size to expand an area in which LTCC is exposed.

### Second Preferred Embodiment

FIGS. 6 to 9 are sectional views showing an electronic device in its finished state according to a second preferred embodiment of the present invention, and showing process steps of manufacturing the electronic device. Electrodes and other components to which the electronic device element 1 is to be connected are formed in the same way as that of the first preferred embodiment, and are not described accordingly.

As shown in FIG. 6, a stacked structure 712 formed in a process of forming a ceramic body of the second preferred embodiment differs from the stacked structure 711 of the first preferred embodiment in that, a frame 31 is provided on the upper surface of the base 2, and space 31a (to become a cavity 3a after being sintered) is defined by the inner peripheral surface of the frame 31 and the upper surface of the base 2.

The first heat transfer layer 8, on which the electronic device element 1 is to be arranged, is formed in a central area of the upper surface of the stacked structure 712 inside the space 31a of the frame 31. The first heat dissipation layer 9 is formed in a central area of the lower surface of the stacked structure 712 (to become the base 2 after being sintered). Alternatively, the first heat transfer layer 8 and the first heat dissipation layer 9 may be formed after the stacked structure 712 is fired to form the base 2.

The vias 4 are defined in each of the ceramic sheets 21. The second heat transfer layer 52 is formed in the same way as that of the first preferred embodiment.

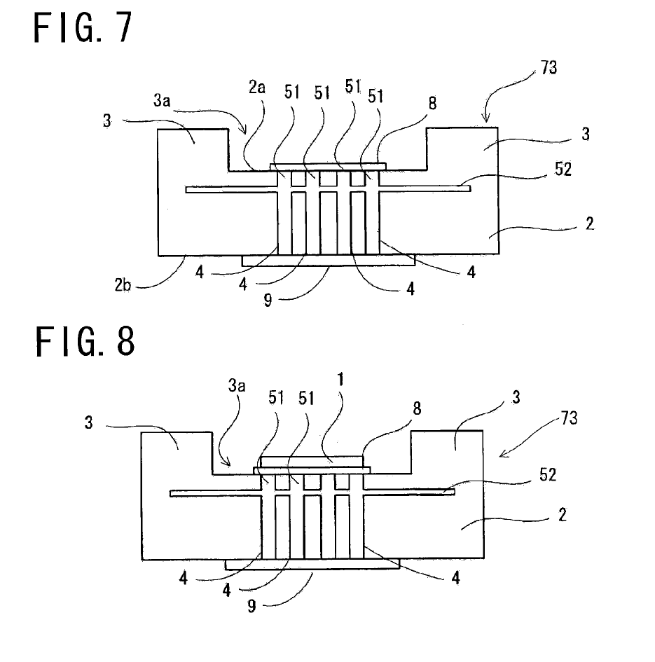

The stacked structure 712 and the frame 31 formed in the process of forming the ceramic body are fired in a subsequent firing process. As a result, the base 2 and the frame 31 are joined together to form a package 73 to contain an electronic device element shown in FIG. 7.

As a result of sintering of the frame 31, the cavity 3a is defined by the inner peripheral surface of the frame 31 and the upper surface of the base 2. Here, it is assumed that a light emitting device element is employed as the electronic device element 1. In this case, like the second heat transfer layer 52 described in the first preferred embodiment, the inner surface of the cavity 3a serves as a reflecting layer. Not only providing better heat dissipation capability, but this also allows light emitted from the light emitting device element to efficiently reflect off both the upper surface of the base 2 and the inner peripheral surface of the cavity 3a.

In the second preferred embodiment, low temperature co-fired ceramic (LTCC) is used as a material of the base 2 and the frame 31, so it can be fired at a temperature from 800° C. to 1000° C.

In a subsequent process of arranging the electronic device element 1, as shown in FIG. 8, the electronic device element 1 is arranged on the first heat transfer layer 8 in the package 73 formed in the firing process.

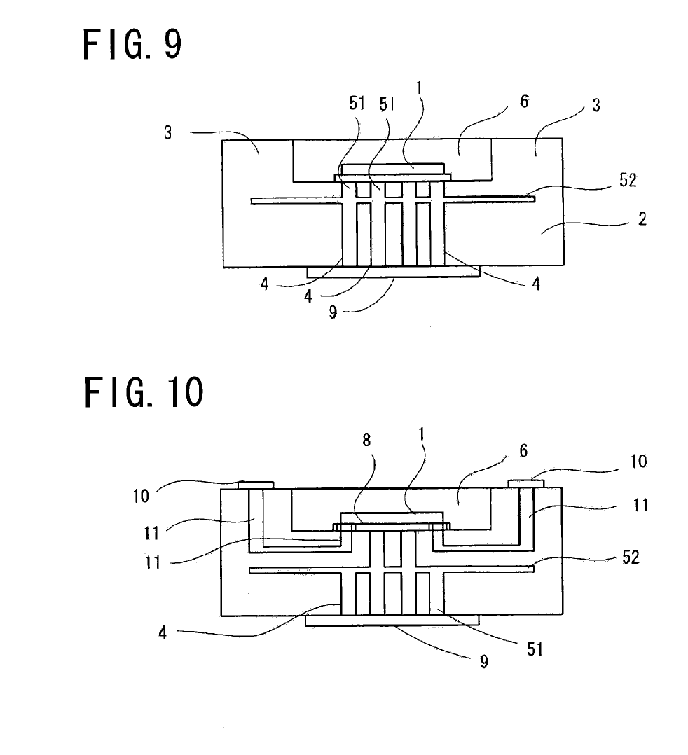

In a subsequent resin applying process, the resin 6 containing a fluorescent substance is applied to fill the cavity 3a as shown in FIG. 9, and the applied resin 6 is cured. Then, the electronic device according to the second preferred embodiment is completed.

The completed electronic device achieves the same heat dissipation effect as that of the electronic device of the first preferred embodiment. Further, when a light emitting device element is employed as the electronic device element 1, the presence of the cavity 3a formed in the electronic device realizes efficient reflection of light emitted from the light emitting device element.

FIG. 10 shows an example of an alternative structure. In the structure shown in FIG. 10, the electrodes 10 are formed on the upper surface of the frame 31. Further, the vias 11 are each defined in the base 2 and the frame 31 so as to extend from the upper surface of the frame 31 to reach part of the upper surface of the base 2 that serves as the bottom surface of the cavity 3a, and thereby the electrodes 10 and the electronic device element 1 are electrically connected each other.

### Third Preferred Embodiment

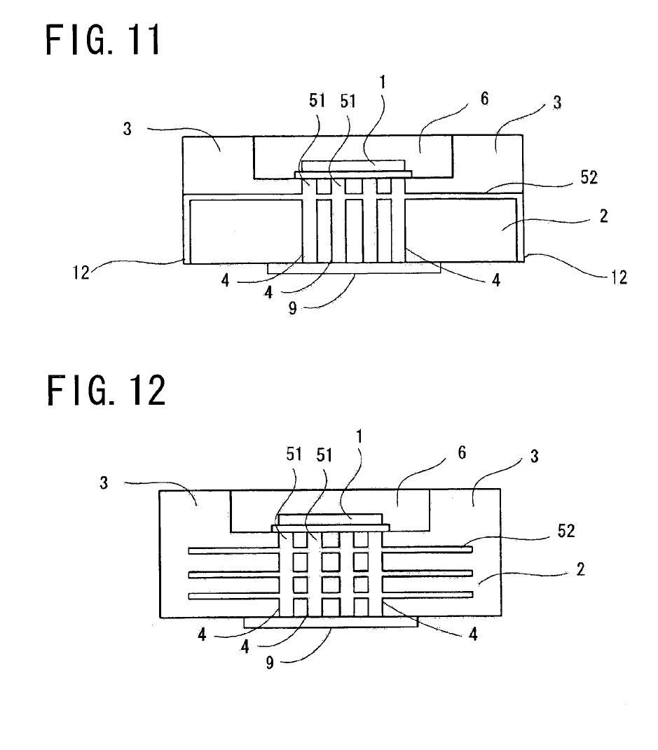

A third preferred embodiment of the present invention is described by referring to FIG. 11. An electronic device of the third preferred embodiment differs from that of the second preferred embodiment in that, the formation of the second heat transfer layer 52 is such that it is exposed at side surfaces of the base 2. The structure and process steps of manufacturing the electronic device of the third preferred embodiment are otherwise the same as those of the second preferred embodiment.

In the electronic device of the third preferred embodiment, the second heat transfer layer 52 is exposed at the side surfaces of the base 2. This provides improved capability of heat dissipation from the base 2 to outside. Further, forming surface-exposed portions at side surfaces of the second heat transfer layer 52 provides better capability of heat dissipation to the outside of the base 2. Besides, forming lateral heat transfer layers 12 at the side surfaces of the second heat transfer layer 52 as shown in FIG. 11 results in formation of a fillet at the time of soldering to a circuit board. Thus, the third preferred embodiment achieves improved heat dissipation capability as compared to those provided by the first and second preferred embodiments.

### Fourth Preferred Embodiment

A fourth preferred embodiment of the present invention is described by referring to FIG. 12. An electronic device of the fourth preferred embodiment differs from that of the second preferred embodiment in that, it includes not only one second heat transfer layer 52, but it includes a plurality of horizontally extending second heat transfer layers 52 arranged in a direction in which the vias 4 extend. The structure and process steps of manufacturing the electronic device of the fourth preferred embodiment are otherwise the same as those of the second preferred embodiment.

The electronic device of the fourth preferred embodiment includes the plurality of second heat transfer layers 52. This increases the amount of heat to be transferred to the base 2 as compared to the second preferred embodiment, thereby improving heat dissipation capability. Further, the existence of the plurality of second heat transfer layers 52 facilitates control of warpage of a package.

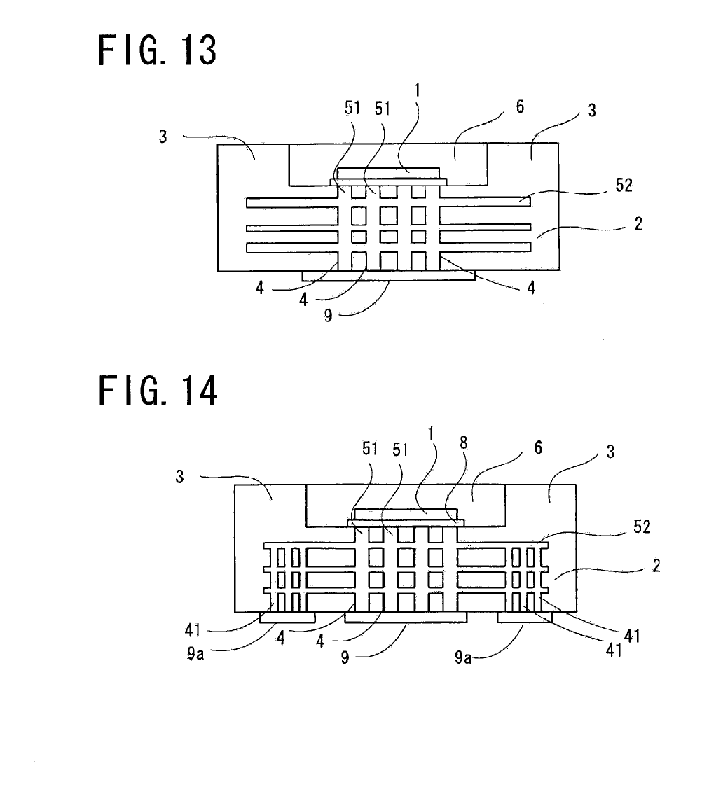

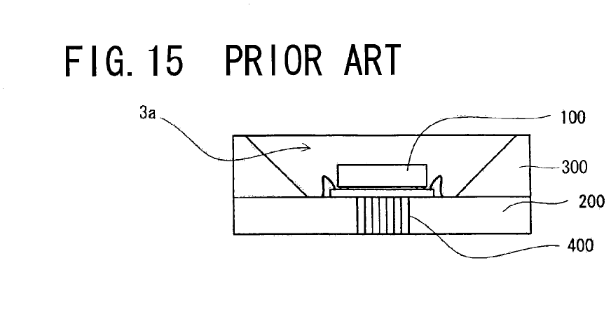

Further, the plurality of second heat transfer layers 52 buried in the base 2 may be changed in their respective thicknesses in a direction substantially vertical to the upper surface of the base 2 as shown in FIG. 13. This realizes precise control of the warpage of the package. So, the electronic device of the fourth preferred embodiment provides improved heat dissipation capability and improved precision of warpage control as compared to those provided by the first to third preferred embodiments.

As shown in FIG. 14, the base 2 may include side vias 41 formed therein each of which extends from a portion of each of the second heat transfer layers 52 defined above the peripheral area of the lower surface of the base 2 to reach the lower surface of the base 2, and then connects to a second heat dissipation layer 9a. This provides coupling between the second heat dissipation layer 9a and the first heat dissipation layer 9. The side vias 41 are filled with a metallic material of high thermal conductivity.

The electronic device of the fourth preferred embodiment provides improved heat dissipation capability as compared to those provided by the first to third preferred embodiments.

The structure of each part of the present invention is not limited to that shown in the preferred embodiment described above. Various modifications may be devised within the technical scope defined in claims.

1. An electronic device, comprising:
a base made of a ceramic material;
an electronic device element arranged in a central area of the upper surface of the base, in a way that the electronic device element is placed on a first heat transfer layer made of a metallic material;
a first heat dissipation layer made of a metallic material, and which is formed in a central area of the lower surface of the base;
a plurality of thermal vias made of a metallic material and arranged in the base, and which connects the first heat transfer layer and the first heat dissipation layer; and
a second heat transfer layer made of a metallic material and buried in the base, the second heat transfer layer crossing the plurality of thermal vias, while extending from a position above a central area of the lower surface of the base to a position above a peripheral area of the lower surface of the base.

2. The electronic device according to claim 1, further comprising:
a second heat dissipation layer made of a metallic material, and which is formed in the peripheral area of the lower surface of the base; and
a plurality of second thermal vias made of a metallic material and buried in the base, and which connects the second heat transfer layer and the second heat dissipation layer.

3. The electronic device according to claim 1, wherein the second heat transfer layer extends to reach a side surface of the base at which an end portion of the second heat transfer layer is exposed.

4. The electronic device according to claim 1, further comprising a frame made of a ceramic material and arranged on the upper surface of the base, wherein
the frame has a cavity formed therein defined by the inner peripheral surface of the frame and the upper surface of the base, and
the electronic device element is arranged in the cavity.

5. The electronic device according to claim 1, further comprising a side via buried in the base, and which extends from a portion of the second heat transfer layer defined above the peripheral area of the lower surface of the base to reach the lower surface of the base.
